(19) United States
(12) Patent Application Publication
(10) Pub. No.: US 2015/0009768 A1
(43) Pub. Date: Jan. 8, 2015

(54) SEMICONDUCTOR DEVICE, SEMICONDUCTOR MEMORY DEVICE, AND METHOD FOR DRIVING THE SAME

(71) Applicant: SK hynix Inc., Icheon-si Gyeonggi-do (KR)

(72) Inventor: Nam Kyu JANG, Icheon-si Gyeonggi-do (KR)

(73) Assignee: SK hynix Inc., Icheon-si Gyeonggi-do (KR)

(21) Appl. No.: 14/084,855

(22) Filed: Nov. 20, 2013

(30) Foreign Application Priority Data
Jul. 8, 2013 (KR) 10-2013-0079550

(51) Int. Cl. G11C 11/4076

(52) U.S. Cl. CPC G11C 11/4076
USPC 365/194

(57) ABSTRACT

A semiconductor device includes a command decoder configured to decode a command and generate a composite command; a first generation block configured to generate a first control signal for performing a first operation based on the composite command; a delay control block configured to delay the composite command by a predetermined time and output a delayed composite command; and a second generation block configured to generate a second control signal for performing a second operation based on the delayed composite command.

### CROSS-REFERENCES TO RELATED APPLICATION

The present application claims priority under 35 U.S.C. §119(a) to Korean application number 10-2013-0079550, filed on Jul. 8, 2013, in the Korean Intellectual Property Office, which is incorporated herein by reference in its entirety.

### BACKGROUND

1. Technical Field

Various embodiments relate to a semiconductor device, and more particularly, to a semiconductor memory device which includes a unit for controlling an activating operation and a method for driving the same.

2. Related Art

A semiconductor memory device is a memory device which is realized using a semiconductor such as silicon (Si), germanium (Ge), gallium arsenide (GaAs) and indium phosphide (InP). A semiconductor memory device is generally classified into a volatile memory device and a nonvolatile memory device.

A volatile memory device is a memory device in which stored data is removed when a power supply is interrupted. A volatile memory device includes an SRAM (static RAM), a DRAM (dynamic RAM) and an SDRAM (synchronous DRAM).

In general, a semiconductor memory device such as a DRAM operates in response to commands and addresses which are applied from an exterior. The commands and addresses are applied to the semiconductor memory device through pins. In order to reduce the size of a semiconductor memory device, researches for decreasing the number of pins have been made. If the number of pins provided in a semiconductor memory device is decreased, the number of bits by which the commands and the addresses to be applied to the semiconductor memory device may be inputted at a time is decreased. In a semiconductor memory device, operation modes are designated by combinations of bits of a plurality of command signals. If the number of pins allocated to commands and addresses is decreased, commands and addresses for setting precharge and active operations should be inputted through several times.

### SUMMARY

The present disclosure allows at least two operations to be performed through one command when operating a semiconductor device. In detail, a semiconductor memory device and a method for driving the same, wherein commands for performing precharge and active operations are not separately provided and instead the two operations may be performed through one command, are described herein.

In an embodiment of the present invention, a semiconductor device includes: a command decoder configured to decode a command and generate a composite command; a first generation block configured to generate a first control signal for performing a first operation based on the composite command; a delay control block configured to delay the composite command by a predetermined time and output a delayed composite command; and a second generation block configured to generate a second control signal for performing a second operation based on the delayed composite command.

In an embodiment of the present invention, a semiconductor memory device includes: a command decoder configured to decode a command and generate a precharge active command; a first generation block configured to generate a precharge control signal based on the precharge active command; a delay control block configured to delay the precharge active command by a predetermined time and output a delayed precharge active command; a second generation block configured to generate an active control signal based on the delayed precharge active command; and a bank control block configured to control operations of a memory bank based on the precharge control signal and the active control signal.

In an embodiment of the present invention, a method for driving a semiconductor memory device may include: decoding a command inputted and generating a precharge active command; delaying the precharge active command by a predetermined time and generating a delayed precharge active command; and activating a memory bank based on the delayed precharge active command.

In an embodiment of the present invention, a semiconductor device includes: a command decoder configured to decode a command and an address and generate a precharge active command; a first generation block configured to generate a precharge control signal based on the precharge active command; a delay control block configured to delay the precharge active command by a predetermined time; and a second generation block configured to generate an active control signal based on the delayed precharge active command. For example, the predetermined time is defined as time ensured until the active control signal is generated for a next active operation after the precharge control signal is generated.

Thanks to the above embodiments, the semiconductor device according to the present disclosure may perform a plurality of operations on the basis of one command.

In the semiconductor memory device and the method for driving the same according to the embodiments of the present disclosure, precharge and active operations of the semiconductor memory device may be efficiently controlled.

In the semiconductor memory device and the method for driving the same according to the embodiments of the present disclosure, because commands and addresses are not provided separately for the precharge operation and the active operation, a time required to set the operations may be shortened.

### BRIEF DESCRIPTION OF THE DRAWINGS

Features, aspects, and embodiments are described in conjunction with the attached drawings, in which:

FIG. 1 is a block diagram showing a semiconductor memory device in accordance with an embodiment;

FIG. 2 is a block diagram showing an embodiment of the delay control block of FIG. 1;

FIG. 3 is a circuit diagram showing an embodiment of the oscillator control unit of FIG. 2;

FIG. 4 is a circuit diagram showing an embodiment of the oscillator of FIG. 2;

FIG. 5 is a timing diagram explaining operations of the semiconductor memory device in accordance with an embodiment; and

FIG. 6 is a circuit diagram showing an embodiment of the bank control block of FIG. 1.

### DETAILED DESCRIPTION

Hereinafter, a semiconductor device, a semiconductor memory device, and a method for driving the same according to the present invention will be described below with reference to the accompanying drawings through various embodiments.

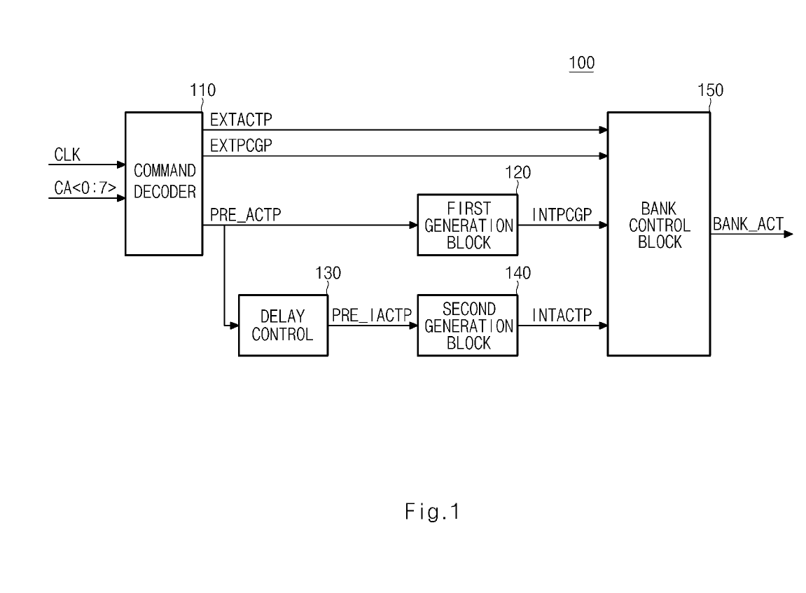

FIG. 1 is a block diagram showing a semiconductor memory device according to an embodiment of the present invention.

Referring to FIG. 1, a semiconductor memory device 100 according to an embodiment of the present invention may include a command decoder 110, a first generation block 120, a delay control block 130, a second generation block 140, and a bank control block 150.

The command decoder 110 may decode a command and an address which are inputted from an exterior, and generate a precharge active command PRE_ACTP. While the precharge active command PRE_ACTP is exemplarily used for the sake of convenience in explanation, it is to be noted that, in the present disclosure, a composite command for allowing a plurality of operations to be performed may be generated by decoding a command and an address which are inputted from an outside.

In an embodiment, the precharge active command PRE_ACTP may indicate a command which causes a precharge operation to be performed and then an active operation to be performed after a predetermined time has elapsed, for a memory bank (not shown) included in a semiconductor memory device. That is to say, through the input of one command as the precharge active command PRE_ACTP, the precharge operation and the active operation may be sequentially performed with a predetermined time.

Without a limiting sense, the composite command described above may mean a command for allowing at least two operations to be performed, and the at least two operations may correspond to the precharge operation and the active operation.

In the present disclosure, in the case where the command decoder 110 generates the precharge active command PRE_ACTP on the basis of a command and an address which are applied from an exterior, it is meant that the semiconductor memory device 100 may operate under a special operation mode.

According to an embodiment, commands for initiating the precharge operation and the active operation to be respectively performed may be provided from the command decoder 110. In this case, in order to perform the respective operations, after causing the first generation block 120 to generate a precharge control signal INTPCGP, the command decoder 110 may cause the second generation block 140 to generate an active control signal INTACTP after a predetermined time has elapsed. For instance, a delayed precharge active command PRE_IACTP provided to the second generation block 140 may not be based on the precharge active command PRE_ACTP, but may be directly provided from the command decoder 110.

Further, the command decoder 110 may decode a command and an address which are inputted from an exterior, and generate a precharge command EXTPCGP and an active command EXTACTP. Unlike the precharge active command PRE_ACTP which initiates the two operations including the precharge operation and the active operation to be sequentially performed as described above, the precharge command EXTPCGP and the active command EXTACTP may respectively initiate a precharge operation and an active operation to be performed. The generated precharge command EXTPCGP and active command EXTACTP may be transferred to the bank control block 150.

In the present disclosure, in the case where the command decoder 110 generates the precharge command EXTPCGP and the active command EXTACTP on the basis of a command and an address which are applied from an outside, it is meant that the semiconductor memory device 100 may operate under a normal operation mode.

In the normal operation mode, the bank control block 150 may precharge or activate a memory bank (not shown) on the basis of the precharge command EXTPCGP and the active command EXTACTP. Here, precharge means an operation of charging the voltage level of bit lines connected to memory cells, to a predetermined voltage level before writing data to the memory cells or reading data from the memory cells. Activation may mean an operation of applying a voltage enough to activate word lines of the memory bank to select memory cells.

Hereinafter, descriptions will be mainly made for the case where the semiconductor memory device 100 operates under the special operation mode.

The first generation block 120 may generate the precharge control signal INTPCGP on the basis of the precharge active command PRE_ACTP which is transferred from the command decoder 110. The generated precharge control signal INTPCGP may be provided to the bank control block 150.

The delay control block 130 may delay the precharge active command PRE_ACTP transferred from the command decoder 110, by a predetermined time. The predetermined time may be defined as, for example, t_{RP} (a precharge to active delay), that is, a time that should be ensured until the active control signal INTACTP is generated for a next active operation after the precharge control signal INTPCGP is generated. The delay control block 130 may generate the delayed precharge active command PRE_IACTP and provide the delayed precharge active command PRE_IACTP to the second generation block 140.

The second generation block 140 may be configured to generate the active control signal INTACTP on the basis of the delayed precharge active command PRE_IACTP delayed by the predetermined time. The generated active control signal INTACTP may be provided to the bank control block 150.

The bank control block 150 may be configured to precharge or activate a memory bank (not shown) on the basis of the precharge control signal INTPCGP and the active control signal INTACTP which are respectively transferred from the first generation block 120 and the second generation block 140. In detail, the bank control block 150 may precharge the memory bank on the basis of the precharge control signal INTPCGP, and may activate the memory bank on the basis of the active control signal INTACTP which is transferred after the predetermined time (for example, t_{RP}).

That is to say, the semiconductor memory device 100 according to an embodiment of the present invention may precharge a memory bank (not shown) and then activate the memory bank after the predetermined time (for example, t_{RP}) without application of a separate active command, on the basis of the generated precharge active command PRE_ACTP. Accordingly, the semiconductor memory device 100 in accordance with an embodiment of the present disclosure may efficiently control the precharge and active operations of a memory bank even in the case where the number of command/address pins is decreased.

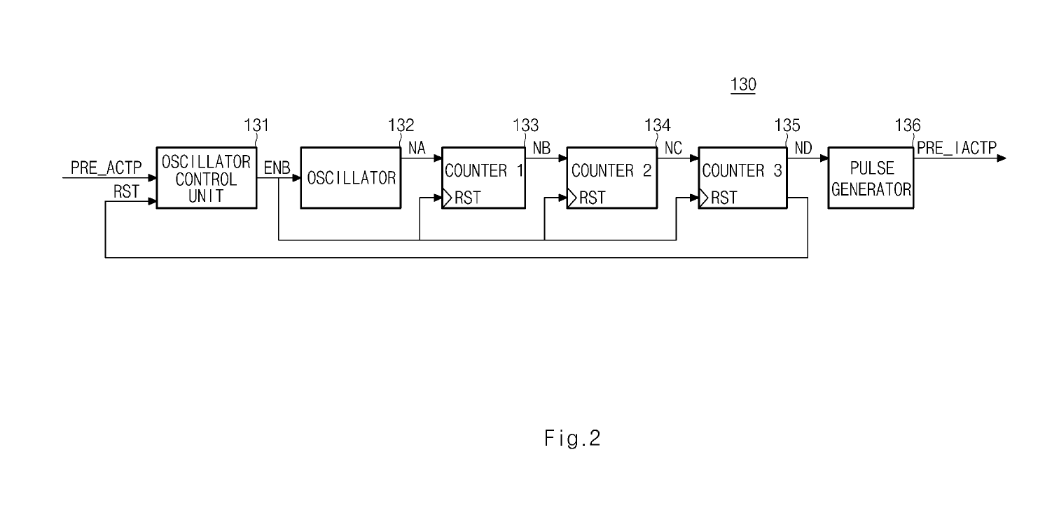

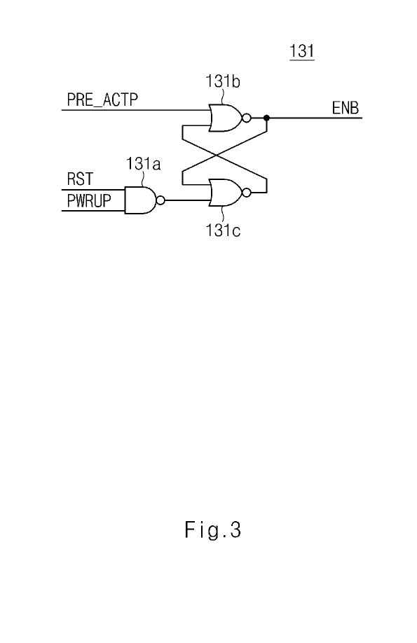

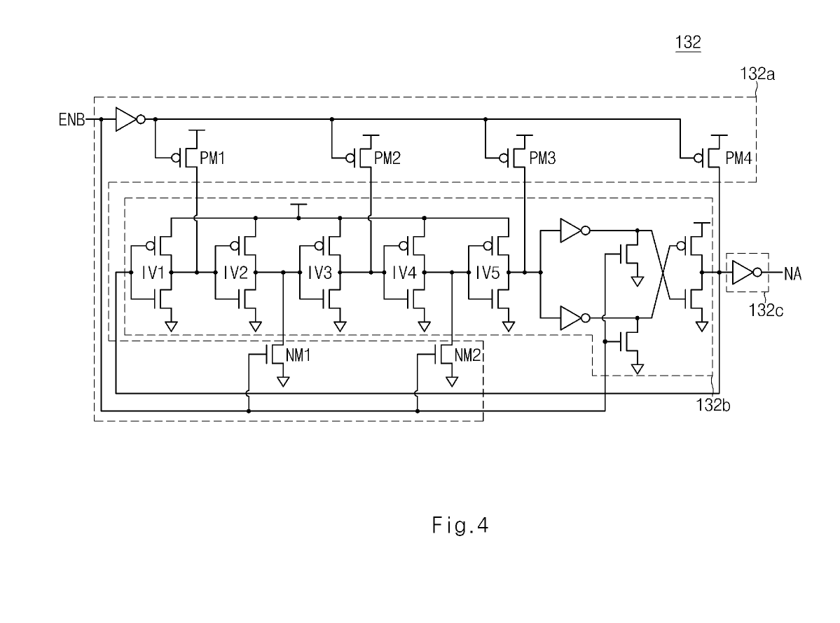

FIG. 2 is a block diagram showing an embodiment of the delay control block of FIG. 1. FIG. 3 is a circuit diagram showing an embodiment of the oscillator control unit of FIG. 2. FIG. 4 is a circuit diagram showing an embodiment of the oscillator of FIG. 2.

First, referring to FIG. 2, the delay control block 130 may include an oscillator control unit 131, an oscillator 132, first to third counters 133, 134 and 135, and a pulse generator 136.

The oscillator control unit 131 may be configured to control the driving of the oscillator 132. The oscillator control unit 131 may be inputted with the precharge active command PRE_ACTP and a reset signal RST, and output an enable signal ENB. Detailed operations of the oscillator control unit 131 will be described below with reference to FIG. 3.

Referring to FIG. 3, the oscillator control unit 131 may include a logic gate 131a which is inputted with the reset signal RST and a power-up signal PWRUP, and a latch circuit 131b and 131c which latches the precharge active command PRE_ACTP. While the logic gate 131a may be, for example, a logic gate which performs a NAND operation, the present disclosure is not limited to such, and it is to be noted that the logic gate 131a may be configured using one or a combination of various logic gates.

While the latch circuit 131b and 131c may be configured by two logic gates which perform logical NOR operations, the present disclosure is not limited to such, and it is to be noted that the latch circuit 131b and 131c may be configured by a combination of various logic gates. In an embodiment, the latch circuit 131b and 131c may constitute an RS latch.

The logic gate 131a may output a logic low value as the reset signal RST is enabled to a logic high. The power-up signal PWRUP may be a signal which is activated when power is applied. Since the semiconductor memory device 100 may operate when power is applied, the power-up signal PWRUP may be assumed to have a logic high. In the case where the latch circuit 131b and 131c constitutes an RS latch as described above, an output signal from the logic gate 131a may correspond to an inverted value of the reset signal RST when the power-up signal PWRUP is the logic high.

The latch circuit 131b and 131c may output the enable signal ENB which has a logic low value when the precharge active command PRE_ACTP is a logic high and the output of the logic gate 131a is the logic low. The generated enable signal ENB may be transferred to the oscillator 132.

Referring to FIG. 4, the oscillator 132 may include a driving section 132a, an oscillating section 132b, and an output buffer 132c.

The driving section 132a may be configured to drive the oscillating section 132b in response to the enable signal ENB inputted thereto. The driving section 132a may include, for example, a plurality of PMOS transistors PM1 to PM4 and a plurality of NMOS transistors NM1 and NM2. The driving section 132a may include at least one inverter to turn on the PMOS transistors PM1 to PM4 and the NMOS transistors NM1 and NM2 in response to the enable signal ENB inputted thereto.

The driving section 132a may retain the voltage levels of the nodes connected to the enable signal ENB, at a constant level. Therefore, when the enable signal ENB is a logic high, the driving section 132a may retain the respective nodes at a predetermined logic state. Accordingly, if the enable signal ENB is the logic high, a first period signal NA may constantly retain a logic low.

Thereafter, if the enable signal ENB is enabled to the logic low, the oscillating section 132b may generate a period signal on the basis of the voltage level that is constantly retained.

The oscillating section 132b may include logic gates (for example, inverters) which are sequentially connected. The oscillating section 132b may be configured as a closed circuit in which the output of a final stage inverter IV5 is transferred as the input of an initial stage inverter IV1. For example, the oscillating section 132b may be realized in the form of a ring oscillator.

While it is shown in FIG. 4 that the number of inverters is 5, the present disclosure is not limited to such, and it is to be noted that the oscillating section 132b may be configured as a closed circuit by using, for example, an odd number of inverters. The oscillating section 132b may generate a period signal which is repeated with a predetermined cycle of a logic high and a logic low. The cycle of the period signal may differ according to a delay time by the respective inverters IV1, IV2, IV3, IV4 and IV5.

The output buffer 132c may be configured to invert the period signal transferred from the oscillating section 132b and output the first period signal NA. Namely, the output buffer 132c may be an inverter which is constituted by a PMOS transistor and an NMOS transistor. The generated first period signal NA may be provided to the first counter 133.

Referring back to FIG. 2, the first counter 133 may be inputted with the first period signal NA and the enable signal ENB. The first counter 133 may be configured to toggle the first period signal NA and generate a second period signal NB. The second counter 134 may be inputted with the second period signal NB and the enable signal ENB. The second counter 134 may be configured to toggle the second period signal NB and generate a third period signal NC. The third counter 135 may be inputted with the third period signal NC and the enable signal ENB. The third counter 135 may be configured to toggle the third period signal NC and generate a fourth period signal ND.

Each of the first to third counters 133, 134 and 135 as general counters may generate a signal which has a cycle twice as long as an inputted signal, and may be reset in response to the enable signal ENB.

The generated fourth period signal ND may be transferred to the oscillator control unit 131 and the pulse generator 135.

The operation of the oscillator control unit 131 may be reset in response to the rising edge of the fourth period signal ND which is generated from the third counter 135. According to this fact, the enable signal ENB generated from the oscillator control unit 131 may be changed to the logic high, and the operations of the first counter 133, the second counter 134 and the third counter 135 may be reset. In other words, the oscillator control unit 131, the first counter 133, the second counter 134 and the third counter 135 may be reset when the predetermined time (for example, tRP) is delayed after the precharge active command PRE_ACTP is activated.

While it is shown in FIG. 2 that three counters 133, 134 and 135 are presented, the present disclosure is not limited to such, and it is sufficient that the number of counters may be determined in such a way as to delay the precharge active command PRE_ACTP to ensure that the bank control block 150 precharges a memory bank (not shown) by the precharge control signal INTPCGP generated from the first generation block 120 and; then activates the memory bank by the active control signal INTACTP generated from the second generation block 140 after the predetermined time (for example, t_{RP}).

The pulse generator 136 may be configured to generate the delayed precharge active command PRE_IACTP in response to the fourth period signal ND transferred from the third counter 135. The delayed precharge active command PRE_IACTP may be delayed by, for example, the predetermined time (t_{RP}), from the precharge active command PRE_ACTP. The delayed precharge active command PRE_IACTP may be provided to the second generation block 140.

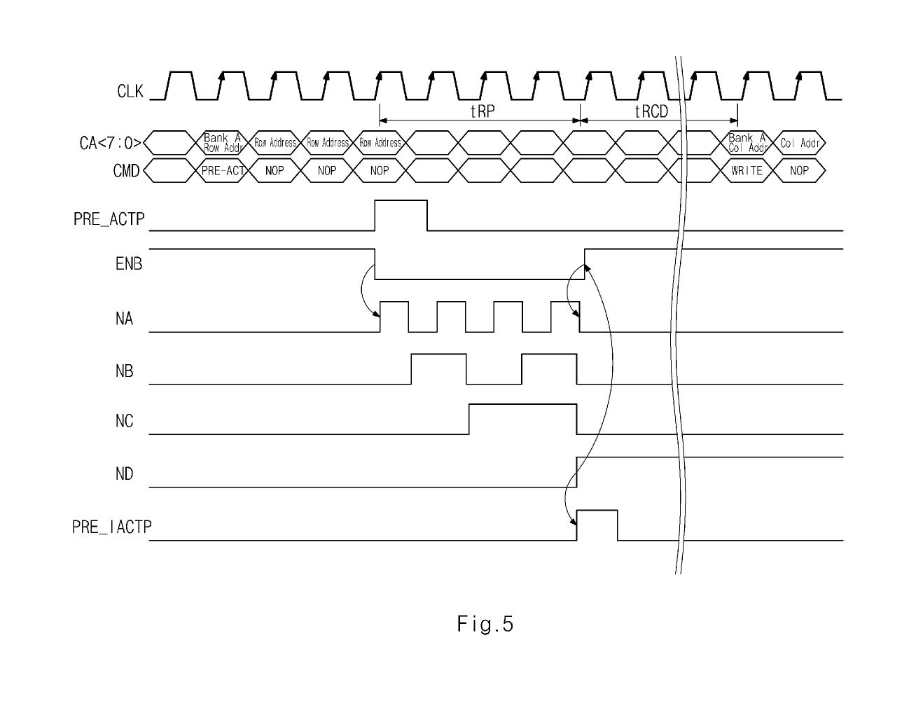

FIG. 5 is a timing diagram explaining operations of the semiconductor memory device according to an embodiment of the present invention.

Referring to FIG. 5, the precharge active command PRE_ACTP may be generated on the basis of a command CMD (i.e. a pre-act command PRE-ACT, a no-operation command NOP, and a write command WRITE) and an address CA<0:7> (i.e. Bank A Row Addr, Row Address, Bank A Col Addr, and Col AddrO) which are inputted from an outside. For example, the precharge active command PRE_ACTP may be generated in synchronization with the rising edge of a clock CLK which is inputted from an exterior.

The precharge active command PRE_ACTP may be applied to the first generation block 120, and the bank control block 150 may precharge a memory bank (not shown) on the basis of the precharge control signal INTPCGP generated from the first generation block 120.

As the precharge active command PRE_ACTP is generated, the enable signal ENB may be activated. While it is shown in FIG. 5 that the enable signal ENB is activated to the logic low, the present disclosure is not limited to such.

If the enable signal ENB is activated, the driving section 132a of the oscillator 132 may be turned off, and the oscillator 132 may generate the first period signal NA. The cycle of the first period signal NA may be delayed through the first counter 133, the second counter 134 and the third counter 135. The pulse generator 136 may generate the delayed precharge active command PRE_IACTP in response to the rising edge of the fourth period signal ND generated by the third counter 135.

The delayed precharge active command PRE_IACTP may be generated by being delayed by four clocks from the precharge active command PRE_ACTP. While it is shown in FIG. 5 that the time delayed by the four clocks corresponds to tRP, the present disclosure is not limited to such.

The delayed precharge active command PRE_IACTP may be applied to the second generation block 140. The bank control block 150 may activate a memory bank (not shown) on the basis of the active control signal INTACTP generated from the second generation block 140. Also, a read/write operation may be performed for the memory bank when tRCD (a row address to column address delay) has passed after the memory bank was activated. Here, tRCD may be defined as a time that is ensured until the read/write operation is performed after the memory bank is activated, that is, word lines are activated.

Accordingly, as can be readily seen from the above descriptions, the semiconductor memory device 100 according to an embodiment of the present invention may precharge a memory bank (not shown) and then activate the memory bank after the predetermined time (for example, tRP) without application of a separate active command, on the basis of the precharge active command PRE_ACTP.

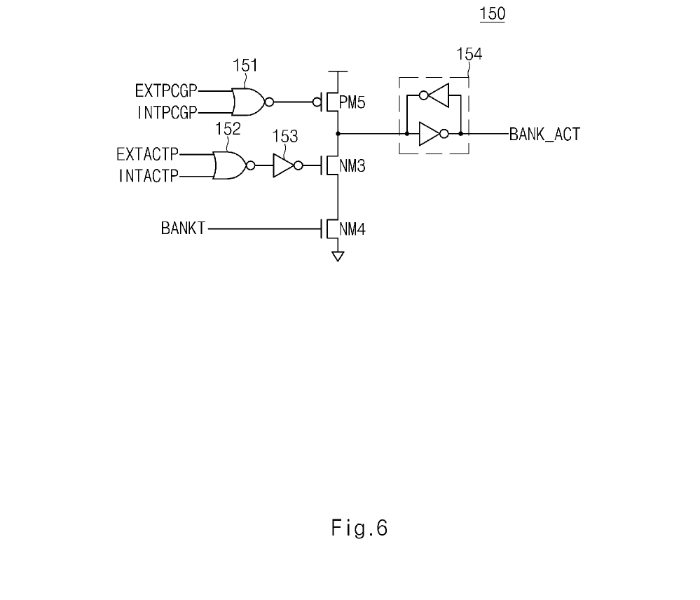

FIG. 6 is a circuit diagram showing an embodiment of the bank control block of FIG. 1. A signal BANKT inputted to the gate of an NMOS transistor NM4 may be a control signal which is generated on the basis of a bank address inputted from an outside.

Referring to FIG. 6, the bank control block 150 may include a first NOR gate 151, a second NOR gate 152, an inverter 153, and a latch circuit 154.

The first NOR gate 151 may perform a logical NOR operation on the precharge command EXTPCGP and the precharge control signal INTPCGP. The first NOR gate 151 may generate an output signal which corresponds to a logic low, in the case where even any one of the precharge command EXTPCGP and the precharge control signal INTPCGP correspond to a logic high.

The second NOR gate 152 may perform a logical NOR operation on the active command EXTACTP and the active control signal INTACTP. That is to say, the second NOR gate 152 may generate an output signal which corresponds to a logic low, in the case where even any one of the active command EXTACTP and the active control signal INTACTP correspond to a logic high. The inverter 153 may invert the output signal of the second NOR gate 152.

A PMOS transistor PM5 and an NMOS transistor NM3 may be connected in series with the NMOS transistor NM4.

The PMOS transistor PM5 may be turned on in the case where at least one of the precharge command EXTPCGP and the precharge control signal INTPCGP correspond to the logic high. In a similar manner, the NMOS transistor NM3 may be turned on in the case where at least one of the active command EXTACTP and the active control signal INTACTP correspond to the logic high. The latch circuit 154 may latch the value that is transferred through a terminal by which the drains of the PMOS transistor PM5 and the NMOS transistor NM3 are connected with each other. FIG. 6 also illustrates a bank active signal BANK_ACT.

Accordingly, a desired memory bank may be precharged or activated in response to a bank address which is inputted from an outside.

In detail, in the case where the semiconductor memory device 100 operates under the normal operation mode, that is, in the case where the precharge command EXTPCGP and/or the active command EXTACTP is generated from a command and an address which are inputted from an outside, the semiconductor memory device 100 may precharge or activate a memory bank in correspondence to the corresponding command.

Also, in the case where the semiconductor memory device 100 operates under the special operation mode, that is, in the case where the precharge active command PRE_ACTP is generated from a command and an address which are inputted from an outside, the semiconductor memory device 100 may precharge a memory bank and then activate the memory bank after the predetermined time tRP.

While certain embodiments have been described above, it will be understood to those skilled in the art that the embodiments described are by way of example only. Accordingly, the semiconductor device, the semiconductor memory device, and the method for driving the same described herein should not be limited based on the described embodiments. Rather, the semiconductor device, the semiconductor memory device, and the method for driving the same described herein should only be limited in light of the claims that follow when taken in conjunction with the above description and accompanying drawings.

What is claimed is:

1. A semiconductor device comprising:
a command decoder configured to decode a command and generate a composite command;
a first generation block configured to generate a first control signal for performing a first operation based on the composite command;
a delay control block configured to delay the composite command by a predetermined time and output a delayed composite command; and
a second generation block configured to generate a second control signal for performing a second operation based on the delayed composite command.

2. The semiconductor device according to claim 1, wherein the first operation corresponds to a precharge operation of the semiconductor device, and the second operation corresponds to an active operation of the semiconductor device.

3. The semiconductor device according to claim 2, wherein the predetermined time corresponds to a precharge active standby time (tRP).

4. The semiconductor device according to claim 1, further comprising:
a control block configured to control the first and second operations.

5. A semiconductor memory device comprising:
a command decoder configured to decode a command and generate a precharge active command;
a first generation block configured to generate a precharge control signal based on the precharge active command;
a delay control block configured to delay the precharge active command by a predetermined time and output a delayed precharge active command;
a second generation block configured to generate an active control signal based on the delayed precharge active command; and
a bank control block configured to control operations of a memory bank based on the precharge control signal and the active control signal.

6. The semiconductor memory device according to claim 5, wherein the bank control block precharges the memory bank on the basis of the precharge control signal, and activates the memory bank after the predetermined time.

7. The semiconductor memory device according to claim 6, wherein the predetermined time corresponds to a precharge active standby time (tRP).

8. The semiconductor memory device according to claim 5, wherein the delay control block comprises:
an oscillator configured to generate a period signal;
an oscillator control unit configured to control driving of the oscillator;
a delay unit configured to sequentially delay the period signal and output resultant signals; and
a pulse generator configured to generate the delayed precharge active command in response to a delayed period signal which is finally outputted from the delay unit.

9. The semiconductor memory device according to claim 8, wherein the delay unit comprises at least one counter which toggles the period signal.

10. The semiconductor memory device according to claim 8, wherein the oscillator control unit performs a logic operation for the precharge active command and the delayed period signal which is finally outputted from the delay unit, and provides an enable signal.

11. The semiconductor memory device according to claim 10, wherein the oscillator generates the period signal in response to the enable signal.

12. The semiconductor memory device according to claim 5, wherein the command decoder provides the precharge active command simultaneously to the delay control block and the first generation block.

13. The semiconductor memory device according to claim 5, wherein the command decoder decodes a command inputted thereto, and respectively generates a precharge command for precharging the memory bank and an active command for activating the memory bank.

14. The semiconductor memory device according to claim 5, wherein the bank control block is separately provided with an active command for performing an active operation for the memory bank and a precharge command for performing a precharge operation for the memory bank.

15. A method for driving a semiconductor memory device, comprising:
decoding a command inputted and generating a precharge active command;
delaying the precharge active command by a predetermined time and generating a delayed precharge active command; and
activating a memory bank based on the delayed precharge active command.

16. The method according to claim 15, further comprising:
generating a precharge control signal on the basis of the precharge active command; and
precharging the memory bank on the basis of the precharge control signal.

17. The method according to claim 16, wherein the generating of the precharge control signal on the basis of the precharge active command and the delaying of the precharge active command by the predetermined time and generating of delayed precharge active command are simultaneously initiated.

18. The method according to claim 16, wherein the predetermined time corresponds to a precharge active standby time (tRP).

19. A semiconductor device comprising:
a command decoder configured to decode a command and an address and generate a precharge active command;
a first generation block configured to generate a precharge control signal based on the precharge active command;
a delay control block configured to delay the precharge active command by a predetermined time; and
a second generation block configured to generate an active control signal based on the delayed precharge active command.

20. The semiconductor device of claim 19, wherein the predetermined time is defined as time ensured until the active control signal is generated for a next active operation after the precharge control signal is generated.
